(19) United States
(12) Patent Application Publication
(10) Pub. No.: US 2012/0241069 A1
(43) Pub. Date: Sep. 27, 2012

(54) Direct Synthesis of Patterned Graphene by Deposition

(75) Inventors: Mario Hofmann, Somerville, MA (US); Jing Kong, Winchester, MA (US)

(73) Assignee: MASSACHUSETTS INSTITUTE OF TECHNOLOGY, Cambridge, MA (US)

(21) Appl. No.: 13/425,659

(22) Filed: Mar. 21, 2012

Related U.S. Application Data
(60) Provisional application No. 61/466,092, filed on Mar. 22, 2011.

(51) Int. Cl. C23C 16/26; B32B 37/02; B32B 9/04; C01B 31/02; B32B 3/10; B82Y 30/00; B82Y 40/00

(52) U.S. Cl. 156/60; 423/448; 427/249.1; 428/195.1; 428/210; 428/209; 977/891; 977/734

(57) ABSTRACT

A graphene pattern is fabricated by forming a pattern of passivation material on a growth substrate. The pattern of passivation material defines an inverse pattern of exposed surface on the growth substrate. A carbon-containing gas is supplied to the inverse pattern of the exposed surface of the growth substrate, and patterned graphene is formed from the carbon. The passivation material does not facilitate graphene growth, and the inverse pattern of exposed surface of the growth substrate facilitates graphene growth on the exposed surface of the growth substrate.

### RELATED APPLICATION

This application claims the benefit of U.S. Provisional Application No. 61/466,092, filed 22 Mar. 2011, the entire content of which is incorporated herein by reference.

### GOVERNMENT SUPPORT

The invention was supported, in whole or in part, by Grant 6920363 from the Office of Naval Research and the Department of Defense. The U.S. Government has certain rights in the invention.

### BACKGROUND

Graphene, typically in the form of a single monolayer of graphite (hexagonal carbon structure), has attracted considerable attention in the scientific community in recent years because of its unique physical and chemical properties [see A. K. Geim, et al., “The Rise of Graphene,” Nature Materials 6 (3), 183-191 (2007) and K. S. Novoselov, et al., “Electric Field Effect in Atomically Thin Carbon Films,” Science 306 (5296), 666-669 (2004)]. Many remarkable properties have been predicted and demonstrated in graphene, such as high electron and hole mobilities with a symmetrical electron and hole band structure, high current-carrying capacity, high in-plane thermal conductivity, high tensile strength and high mechanical stability.

Graphene also has significant potential for industrial applications as a transparent electrode [see S. Bae, et al., “Roll-to-roll production of 30-inch graphene films for transparent electrodes,” Nature Nanotechnology 5 (8), 574-578 (2010)], flexible electrical circuits [see K. S. Kim, et al., “Large-scale pattern growth of graphene films for stretchable transparent electrodes,” Nature 457 (7230), 706-710 (2009)], and as a capacitor [see Y. Wang, et al., Journal of Physical Chemistry C 113 (30), 13103-13107 (2009]). Many of these applications require the patterning of graphene into predefined shapes.

Traditionally patterning has been done after synthesis by covering the desired patterns with lithographically generated masks and destructively removing the excess graphene with oxygen plasma, ultra-violet ozone, reactive ion etching, etc. This class of methods can deteriorate the quality of the grown graphene since several lithography steps are generally needed to define mask patterns and to subsequently remove them again. Furthermore, the graphene-electrode-interface is not pristine and affects the performance of the thus fabricated devices.

Another method of generating graphene patterns is the pre-patterning of catalyst material and subsequent synthesis of graphene by chemical vapor deposition (CVD) [see A. Reina, et al., “Large Area, Few-Layer Graphene Films on Arbitrary Substrates by Chemical Vapor Deposition,” Nano Letters 9 (1), 30-35 (2009). However, the high temperatures associated with the CVD process may deteriorate the quality of the deposited structures and limit minimum the feature size.

In still another method, excess graphene is directly destroyed through direct writing using a laser or ion beam.

Each of these methods, however, can suffer from a mixture of disadvantages such as lacking scalability, fabrication speed or restrictions on the target substrate onto which the graphene can transferred. Additionally, traditional patterning techniques rely on the destructive removal of excess graphene through use of oxygen plasma, ultra-violet ozone, reactive ion etching, etc. These techniques can decrease the quality of the graphene and leave rough graphene edges. Furthermore, the material deposition and lift off steps for defining graphene patterns have been shown to affect the doping of the graphene film and the graphene-electrode-interface, thus deteriorating the performance of the fabricated devices.

### SUMMARY

Methods for patterning graphene and associated structures using direct synthesis via vapor deposition and the resulting patterns are described herein. Various embodiments of the structures and methods may include some or all of the elements, features and steps described below.

In these methods, a pattern of passivation material is formed on a surface of a growth substrate, wherein the pattern of passivation material defines an inverse pattern of exposed surface on the growth substrate. A carbon-containing gas is then supplied to the inverse pattern of exposed surface on the growth substrate. The passivation material does not facilitate graphene growth (i.e., it is non-reactive or non-catalytic with respect to the carbon-containing gas or does not provide a surface that is suitable to graphene formation), whereas the inverse pattern of exposed surface on the growth surface may catalytically generate graphene coverage by decomposition of the carbon-containing gas and subsequent incorporation of carbon atoms into the graphene lattice.

Embodiments of this graphene-fabrication method may produce higher-quality graphene devices since the patterning step is carried out before graphene is synthesized; and, thus, the risk of contaminating the graphene in the fabrication process can be reduced. Although attempts have been made to obtain patterned graphene by depositing catalytic substrates in the desired shape and then growing graphene on these substrates, the catalytic approach has a fundamental limitation as to the achievable resolution because the patterned catalyst will restructure itself at the high process temperatures to decrease its surface free energy, resulting in smoothed-out corners and merged features. Furthermore, the deposition of patterns through evaporation increases the production cost compared to rolled foils; and such depositions can result in lower-crystalline-quality substrates, which correlates with lower-quality graphene.

Accordingly, the described technique has the potential to affect both the production of high quality and low cost graphene-based devices for a multitude of different applications, such as high speed electronics, sensors, radiofrequency identification devices (RFIDs), wearable electronics, disposable electronics, displays, transparent circuitry and could be of considerable interest.

### BRIEF DESCRIPTION OF THE DRAWINGS

FIG. 1 shows a pattern of passivation material formed on a metal film coating a growth substrate.

FIG. 2 shows a graphene film formed on sections of the metal film not covered by the passivation material.

FIG. 3 shows a protective support layer applied to the graphene pattern to remove the graphene pattern from the growth substrate.

FIG. 4 shows the graphene pattern transferred onto an arbitrary target substrate.

FIG. 5 is a photographic image of a pattern of aluminum oxide passivation material on a copper foil.

FIG. 6 is a photographic image of patterned graphene transferred onto a flexible, transparent polymeric substrate.

FIG. 7 provides a schematic image of a device that includes a thin film of aluminum oxide as passivation material in contact with a graphene film and a plot of the photo response of the device.

FIG. 8(a) is an optical micrograph of patterned graphene after transfer to a SiO₂ substrate.

FIG. 8(b) is a magnified atomic-force-microscopic image of the patterned graphene shown in FIG. 8(a)

FIG. 8(c) is a Raman map of the G′-band intensity of the same region shown in FIG. 8(b).

FIG. 8(d) provides a representative Raman spectra of the passivated region (top) and the exposed region (bottom) of the graphene pattern of FIGS. 8(a)-(c)

FIG. 9(a) is photographic image of large-scale patterns deposited by ink-jet printing on copper foil.

FIG. 9(b) is a photographic image of patterned graphene film after transfer to plastic substrate.

FIG. 9(c) is an optical micrograph of graphene patterns obtained by photolithographical patterning of the passivation layer.

FIG. 9(d) is a high-magnification image of a graphene pattern shown in FIG. 9(c)

FIG. 9(e) is a photographic image of a graphene sample patterned by micro contact lithographical deposition of a passivation layer.

FIG. 9(f) is an atomic-force-microscopy image of the resulting parallel Al₂O₃ lines shown in FIG. 9(e) with a 700 nm period.

FIG. 10(a) is a photographic image showing a patterned graphene membrane during transfer.

FIG. 10(b) is a schematic image of a graphene electrode structure,

FIG. 10(c) is a photographic image of patterned graphene electrodes on a lens supplying current to a light-emitting diode.

FIG. 10(d) is a scanning-electron-microscopy image of lithographically patterned graphene transferred onto a glass bead.

In the accompanying drawings, like reference characters refer to the same or similar parts throughout the different views; and apostrophes are used to differentiate multiple instances of the same or similar items sharing the same reference numeral. The drawings are not necessarily to scale, emphasis instead being placed upon illustrating particular principles, discussed below.

### DETAILED DESCRIPTION

The foregoing and other features and advantages of various aspects of the invention(s) will be apparent from the following, more-particular description of various concepts and specific embodiments within the broader bounds of the invention(s). Various aspects of the subject matter introduced above and discussed in greater detail below may be implemented in any of numerous ways, as the subject matter is not limited to any particular manner of implementation. Examples of specific implementations and applications are provided primarily for illustrative purposes.

Unless otherwise defined, used or characterized herein, terms that are used herein (including technical and scientific terms) are to be interpreted as having a meaning that is consistent with their accepted meaning in the context of the relevant art and are not to be interpreted in an idealized or overly formal sense unless expressly so defined herein. For example, if a particular composition is referenced, the composition may be substantially, though not perfectly pure, as practical and imperfect realities may apply; e.g., the potential presence of at least trace impurities (e.g., at less than 1 or 2% by weight or volume) can be understood as being within the scope of the description; likewise, if a particular shape is referenced, the shape is intended to include imperfect variations from ideal shapes, e.g., due to machining tolerances.

Although the terms, first, second, third, etc., may be used herein to describe various elements, these elements are not to be limited by these terms. These terms are simply used to distinguish one element from another. Thus, a first element, discussed below, could be termed a second element without departing from the teachings of the exemplary embodiments.

Spatially relative terms, such as “above,” “upper,” “beneath,” “below,” “lower,” and the like, may be used herein for ease of description to describe the relationship of one element to another element, as illustrated in the figures. It will be understood that the spatially relative terms are intended to encompass different orientations of the apparatus in use or operation in addition to the orientation depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

Further still, in this disclosure, when an element is referred to as being “on,” “connected to” or “coupled to” another element, it may be directly on, connected or coupled to the other element or intervening elements may be present unless otherwise specified.

The terminology used herein is for the purpose of describing particular embodiments and is not intended to be limiting of exemplary embodiments. As used herein, the singular forms, “a,” “an” and “the,” are intended to include the plural forms as well, unless the context clearly indicates otherwise. Additionally, the terms, “includes,” “including,” “comprises” and “comprising,” specify the presence of the stated elements or steps but do not preclude the presence or addition of one or more other elements or steps.

As described, below, patterned graphene can be generated through area-selective chemical-vapor-deposition (CVD) growth. The method includes the passivation of defined areas of catalyst material and the subsequent selective growth in unpassivated regions (wherein the graphene will grow preferentially—i.e. with much greater coverage and continuity—in the unpassivated regions). A wide variety of passivation layer materials can be used, and the feasibility of this approach is demonstrated using aluminum. The passivation layer 12 can be non-catalytic with respect to the carbon-containing gas or the passivation layer 12 may be catalytic but not suitable for graphene growth (e.g., due to its composition or surface roughness). In addition to hindering the growth of graphene thereon, the passivation layer can be advantageously formed of a material that is immiscible with the substrate, which may comprise copper, at high temperatures and that has a high melting point to avoid diffusion of the passivation layer on the growth substrate. Any of at several methods of deposition of the passivation layers 12 can be employed (e.g., focused ion beam, evaporation through shadow masks, lithography and evaporation, ink-jet printing of solution) to accommodate demands of resolution, scalability and cost.

In a particular embodiment of the method, a catalytic film formed of copper (or other transition metal, such as nickel, platinum or ruthenium, that catalyzes the dehydrogenation of hydrocarbons or has certain carbon solubility under elevated temperature) is deposited on a silicon dioxide (silica) surface of a substrate 16, e.g., via electro-chemical deposition, electron-beam or thermal evaporation or sputtering. The resulting metal film can be polycrystalline or a single crystal, while the substrate 16 can be silicon with a silicon dioxide surface layer; alternatively the substrate 16 can be formed of quartz. In another alternative embodiment, the entire substrate 16 can be formed of a metal, such as nickel, without the underlying insulating substrate; in this embodiment, however, etching to free the graphene film 18 may not be as readily limited to a thin surface layer (e.g., a thin copper layer) beneath the graphene film 18, resulting in a need for more acid and a longer etching process. A protective oxide layer (e.g., nickel oxide) can be formed on the surface of the metal coating, and the oxide layer can be removed before graphene formation by contacting it with hydrofluoric acid (HF), acetic acid (CH₃COOH), potassium hydroxide (KOH), or sodium hydroxide (NaOH).

In other embodiments, the film may not be catalytic with respect to the hydrocarbons (or other carbon-containing gas) and may only serve to restructure the carbon atoms into graphene. In this case, another means for supplying the carbon atoms (e.g., plasma, hot filament, promoters, etc.) is provided in place of the catalyst.

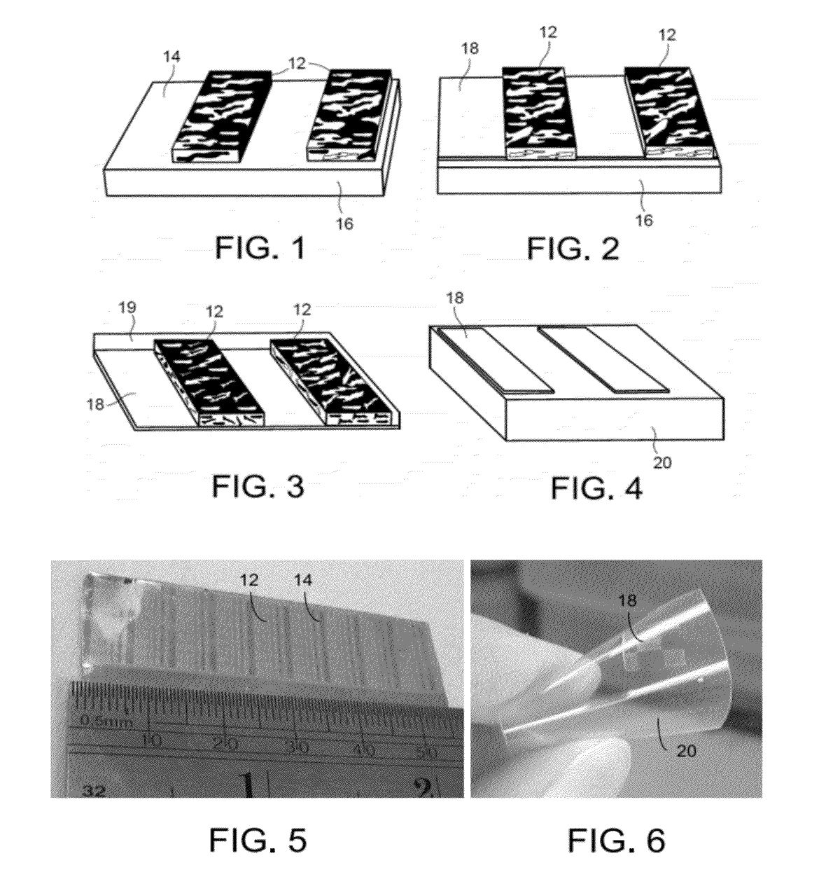

As shown in FIG. 1, a pattern of passivation material 12 can be formed on the metal film 14 that coats the growth substrate 16 by depositing aluminum, for example, via shadow mask aluminum evaporation/deposition; via lithography; or via ink-jet printing, where a print head (as found in an ink jet printer) is filled with a fluid containing an aluminum salt (e.g., AlCl₃) and controlled by a computer to print the aluminum in a defined pattern. The exposed surface of the aluminum can then be oxidized to form an aluminum oxide passivation layer. In other embodiments, silicon can be deposited and oxidized to produce, e.g., a silica (SiO₂) passivation layer. Other materials that can be included in the passivation layer 12 include ceramics (e.g., Si₃N₄, or Al₂O₃), refractory metals (W, Zr or Cr), and metal oxides (MgO or TiO₂) that are temperature resistant and that do not facilitate graphene growth or form an alloy (e.g., NiSi) with the catalyst material. In particular embodiments, alumina (Al₂O₃) is chosen as the passivation layer for graphene growth on a copper substrate because of several desirable properties of Al₂O₃, including the refractory nature of alumina, which prevents it from interacting with the growth substrate and inhibits reshaping of the passivation layer under high temperature. Furthermore, the easy production of alumina and its low cost make it attractive for large-scale industrial applications.

Because the passivation material can be patterned with a high-degree of precision, the subsequently deposited graphene film 18 can have very fine and precise dimensions in a pattern that is the inverse of the pattern of passivation material. A photographic image of a representative pattern of aluminum oxide (serving as the passivation material 12) on copper foil (as the metal layer 14) on a substrate is shown in FIG. 5. In other embodiments, the passivation layer 12 may include a composition that decomposes the hydrocarbon (and may even act as a promoter for the catalyst) but that does not allow formation of a continuous graphene layer extending across the passivation layer 12.

After the pattern of passivation material 12 is formed on the metal-coated substrate 14, 16, the metal-coated substrate 14, 16 with the pattern of passivation material 12 can be loaded into a chemical-vapor-deposition chamber, where it can be heated to 900° C.-1000° C. under a vacuum of 400 mTorr and a flow of 10 standard cubic centimeters per minute (sccm) hydrogen (H₂). Introduction of a carbon-containing gas (e.g., methane CH₄ at 20 sccm) and an increased flow of H₂ of 50 sccm at these high temperatures can initiate and control the deposition of carbon and the restructuring into a graphene film 18 on the metal layer 14 on the substrate 16, as shown in FIG. 2. In other embodiments, other carbon sources, such as any carbon-containing gas—e.g., ethylene, alcohol and/or carbon monoxide, liquid or solid carbon precursors (e.g., polymers or amorphous carbon) can be used to supply the carbon for the graphene film 18.

The graphene film 18 can be continuous across the pattern of catalyst surface defined by the pattern of passivation material 12, and the thickness of the graphene film 18 can be one layer to 10 graphene layers across most of the pattern. In particular embodiments, the graphene film pattern can have very fine dimensions, such as electrically conductive pathways with line widths of about 1 nm or less.

The graphene pattern 18 can then be removed, e.g., by applying a protective support layer 19, as shown in FIG. 3 and as described, e.g., in published US patent application No. 2010/0021708 A1. The protective support layer 19 (formed, e.g., of polymethylmethacrylate, polydimethylsiloxane or polycarbonate) can then be coated on the graphene film 18 to provide support for the graphene film 18 and to maintain its integrity when the graphene film 18 is removed from the growth substrate 16. The surface of the growth substrate 16 is then etched (e.g., with a mild aqueous hydrochloric acid or ferric chloride solution) to release the graphene film 18 and protective support layer 19 from the growth substrate 16. The graphene pattern 18 can furthermore be released using a dry transfer process involving the removal of the graphene film 18 attached to a protective support layer 19 from the growth substrate by applying a force that is large enough to overcome the adhesion between graphene pattern 18 and the growth substrate 16. After being released from the growth substrate 16, the graphene film 18 and protective support layer 19 can be applied onto an arbitrary target substrate 20 (as shown in FIG. 4) for evaluation or use in any of a wide variety of applications. The protective support layer can then be removed from the graphene film 18 after the graphene film 18 is applied to the arbitrary target substrate 20 by slowly flowing a solvent (e.g., a ketone, such as acetone or other organic solvents, such as Chloroform) over the protective support layer. A photographic image of patterned graphene transferred to a flexible, transparent polymeric substrate is shown in FIG. 6.

In other embodiments, the graphene pattern can be directly transferred from the growth substrate to a target substrate with an arbitrarily shaped surface, wherein the target substrate replaces the intermediate support layer in removing the graphene pattern from the growth substrate. In still other embodiments, the growth substrate with the graphene pattern may be the final product, which can be, for example, a non-planar electronics device; i.e., the graphene pattern need not be transferred from the growth substrate to a separate target substrate.

In some embodiments, the passivation layer 12 can be patterned to exhibit nanometer-sized openings (e.g., with a diameter of 1 to 100 nm) that result in graphene patterns of similar size. These nano-dimensioned graphene patterns can provide new functionality due to confinement effects in the graphene (e.g., opening of an electronic band gap, change in magnetic properties due to edge effects, and increased chemical reactivity of graphene).

In some embodiments, the passivation layer 12 can be removed by introducing an etching process step (e.g., via wet chemical etching). The etchant can be applied (a) to the graphene/passivation layer structure residing on the growth substrate 16 after growth, (b) to the graphene/passivation layer structure on the support layer during transfer, or (c) to the graphene/passivation layer structure on the target substrate 20 after transfer. The chemical etchant (e.g., KOH, HCl) is chosen to be selective towards the removal of the passivation layer 12 without affecting the graphene.

In some embodiments, the passivation layer 12 can be retained to provide additional functionality to the graphene layer. As an example, the passivation layer 12 may comprise a semiconducting material (e.g., TiO₂). The interface between the passivation layer 12 and the grown graphene can then exhibit desirable electronic properties, such as rectifying behavior.

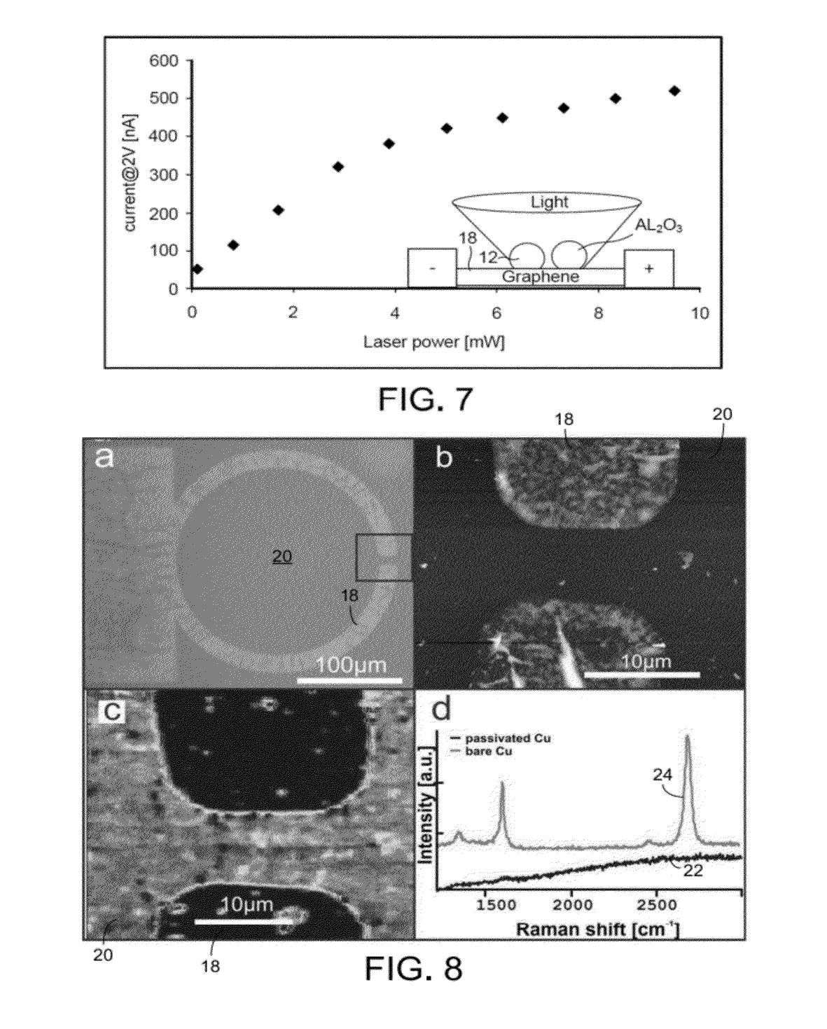

As another example, the passivation layer 12 may comprise a light-sensitive material. The interface between the passivation layer 12 and the grown graphene film can then exhibit a photosensitive charge transfer and result in a photosensitive charge conduction within the graphene. FIG. 7 shows the photo response of a device that includes a thin film of aluminum oxide (3-10 nm thick) as passivation material 12 in contact with a graphene film 18. The plot indicates the current generated with a 2 V bias as a function of incident light power (from a 532 nm laser). The schematics of the device configured for measurement is inset in FIG. 7. As light is shone onto the device, a larger current at a given bias occurs. This response is not observed when illuminating a pure graphene device. We thus infer that the presence of aluminum oxide creates a photo response by injecting photocarriers into graphene. This can be seen as a way of adding functionality to the original graphene device. This photodetector can be employed, for example, as a large-scale, flexible, cheap, transparent photo sensor or camera.

In some embodiments, after the graphene film 18 is transferred to a new arbitrary target substrate 20 and/or after a particular pattern of graphene film 18 is generated, particular areas of the graphene film 18 are doped by one or more chemicals, such as potassium and/or polyethyleneimine, to generate p- or n-type regions for devices. In additional embodiments, a certain area of the graphene film 18 can be intercalated with different molecules.

### Additional Exemplifications:

Exemplification 1:

Based on the above-described process, graphene patterns were generated through lithographical patterning of photoresist on copper foil and subsequent deposition of Al₂O₃ via ALD. The quality of the deposited passivation layer was confirmed by x-ray photoelectron spectroscopy after growth. The passivation layer was not removed but transferred with the patterned graphene to aid alignment of the patterned graphene on the target substrate. Preserving the passivation layer during the transfer process can add functionality to the fabricated device. For example, the fabrication of tunable resistors by varying the deposited amount of Al₂O₃ was demonstrated. Furthermore, because of a predicted beneficial effect of a crystalline alumina dielectric on graphene device performance, the alumina passivation layer can be used as an integrated gate dielectric. A thin, high quality dielectric layer can also be useful in other applications (for example, as spacers in liquid crystal displays).

After growth of a graphene pattern 18 on a growth substrate with a passivation pattern, the patterned graphene was transferred onto a Si/SiO₂ target substrate 20, and an optical micrograph of the patterned graphene 18 is shown in FIG. 8(a). The different regions associated with the passivation layer and the grown graphene can be identified in this image as well as in the atomic force microscopy image provided in FIG. 8(b). The clear boundary between the passivation layer region and the graphene indicates that no diffusion of the Al₂O₃ occurred during the growth process. The feature size seems limited only by the resolution of the deposited patterns. This observation indicates the potential for creating high resolution patterns using the described approach.

The presence and quality of graphene in the area shown in FIG. 8(b) was analyzed by Raman spectroscopy. A Raman map was obtained by taking one Raman spectrum every 100×100 nm, and FIG. 8(c) shows the spatial variation of the G′-band peak intensity. The G′-band feature at ˜2650 cm⁻¹ was chosen for the analysis since it is enhanced in graphene because of a double resonance process and can be considered a characteristic feature of graphene. As expected, the areas covered by graphene can be identified by large G′-peak intensities. The passivation layer region 22 is clearly distinguishable against the bare copper region 24 by the absence of a G′-band feature as well as other Raman peaks that would occur for graphitic materials, as seen in FIG. 8(d). The background in the Al₂O₃ Raman spectrum is assumed to originate from defect-induced photoluminescence of the material, and the weak G-band (˜1600 cm⁻¹) is attributed to amorphous carbon contamination.

The high quality of the graphene grown in the unpassivated areas 24 can be inferred from the sharp Raman peaks and from the low intensity of the defect-induced D-band Raman feature. The D-band intensity was found to increase during a transfer-related annealing step and thus does not only reflect the intrinsic defect density.

Hall measurements in the van-der-Pauw geometry were performed to characterize the electronic mobility of the graphene films, and a value of 650 cm²/Vs was obtained, which is comparable to other graphene films grown with the same CVD procedure.

Exemplification 2:

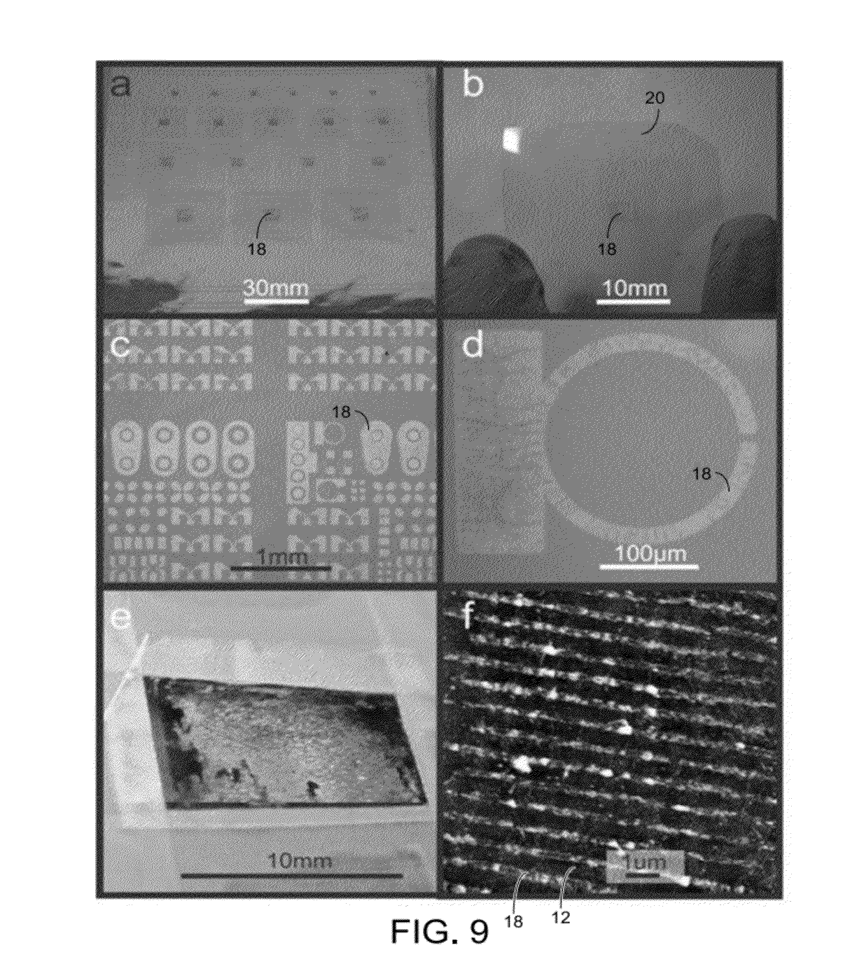

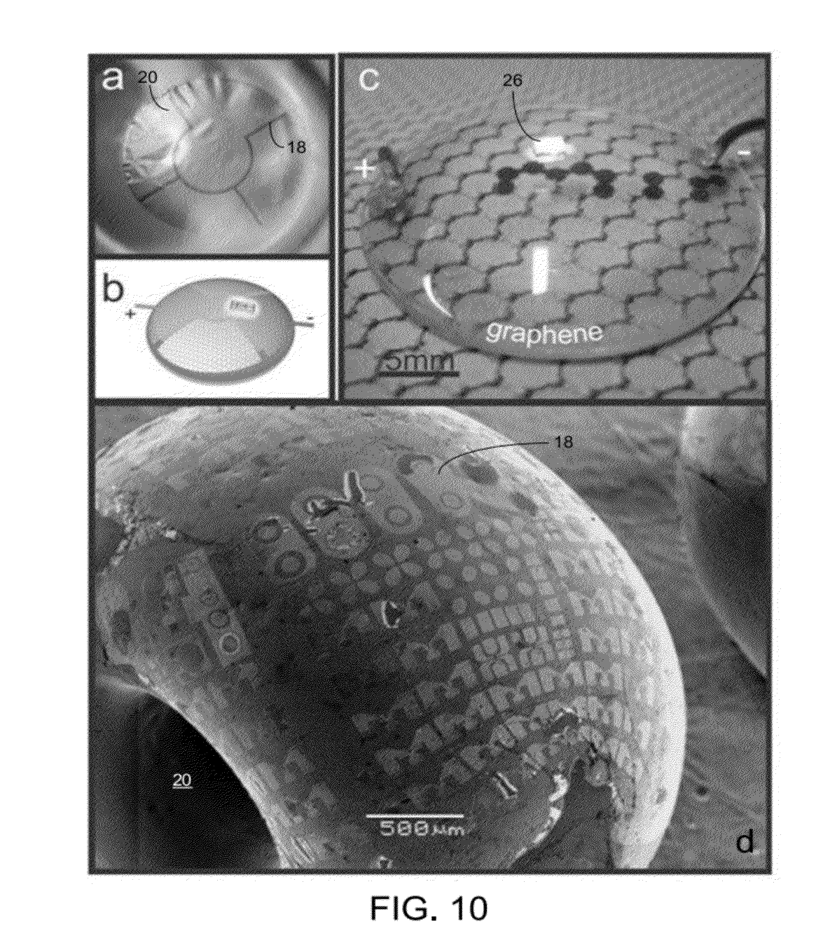

Various methods to deposit the passivation layer can be conceived to accommodate various demands of different applications, such as high resolution, low cost, scalability, etc., and FIGS. 9(a)-(d)Error! Reference source not found. detail several approaches.

Ink jet printing is a proven technique with the ability to generate large areas of medium-resolution patterns at low cost. FIG. 9(a) shows a large (150×250 mm) piece of Cu foil that has been patterned by an ink-jet deposited AlCl₃ precursor. In contact with air, the deposited material will readily oxidize and form the passivation layer. After growth, the graphene film 18 was transferred onto a flexible PET substrate 20, as shown in FIG. 9(b) to demonstrate the feasibility of producing flexible, transparent graphene circuits at low cost. This method is enables the production of graphene-based recyclable electronics, e.g., for radio-frequency identification (RFID) tags.

Micrometer- and nanometer-sized graphene devices have proven their potential for high frequency electronics, photodetectors, etc. FIGS. 9(c) and (d) show the growth of graphene patterns 18 on a high-resolution pre-patterned sample obtained by photolithography and subsequent atomic layer deposition of aluminum oxide. The achievable feature size is limited by the resolution of optical lithography in this exemplification.

Finally, the Al₂O₃ passivation layer can be deposited over large areas at high resolution via microcontact printing, as shown in FIG. 9(e). A polydimethylsiloxane (PDMS) replica of a grating with 700 nm pitch was inked with a solution of AlCl₃ and then pressed onto a Cu foil. This procedure resulted in the fabrication of parallel lines of Al₂O₃ passivation layer 12 (better seen in FIG. 9(f)), which were used to grow arrays of graphene ribbons 18 over large areas, as observed by a light diffraction effect of the resulting sample, as seen in FIG. 9Error! Reference source not found.(e) and confirmed by Raman spectropscopy. The atomic force microscopy seen in FIG. 9Error! Reference source not found.(f) reveals that the graphene ribbons 18 have a width of approximately 300 nm. This result highlights the potential of inexpensively and scalably producing graphene structures that can exploit size-dependent effects, such as quantum dots or nanoribbons for application in novel devices.

The ability to generate high-quality graphene patterns by different methods that are complementary in resolution and cost can increase the commercial appeal of graphene-based devices over existing technologies. Additionally, these graphene patterns can enable new fields of applications because of graphene's unique combination of properties. For example, graphene is a suitable material for non-planar devices because of its ability to closely conform to rough surfaces due to its atomic thickness. This property may render these films useful in applications such as detectors, implantable devices and displays. Conventional lithographical techniques, however, typically only produce graphene patterns on flat substrates, due to a limited depth of focus of the optical exposure units, handling issues, etc. Thus, non-planar substrates are not accessible for high-resolution lithographical patterning. The described direct synthesis technique does not face these limitations since graphene patterning is accomplished before the transfer step and pre-patterned graphene can be placed onto virtually any sample.

Exemplification 3:

The transfer of pre-patterned graphene films onto complex surfaces is demonstrated in FIGS. 10(a)-(d). As a proof of concept, a graphene pattern 18 with four clover-leaf-shaped graphene electrodes (see FIG. 10(a)) was generated by patterning the passivation layer, CVD growth, and transfer onto a glass lens as the target substrate 20 to form a simple electrical circuit (see FIG. 10(b)). Current is directed through a standard light emitting diode 26 (VISHAY-TLMO1000, 1.6×0.8 mm) that was attached onto the graphene layer by silver adhesive (see FIG. 10(c)). This integration of commercially available electronics components into graphene circuits is intended to show their synergy.

As a second example, lithographically pre-patterned graphene was transferred onto a 3 mm-diameter glass bead as the target substrate 20. In the Scanning Electron Microscope (SEM) image in FIG. 10(d), the graphene pattern 18 can be identified by transfer-induced tears in the continuous film. The thickness of the passivation layer 12 was chosen to be small enough (7 nm) to also conform to the spherical surface. This ability to produce micron-sized graphene structures and dielectrics on complex surfaces enables new ways to produce electronics for a variety of applications, such as implantable devices, bio-inspired circuits, etc.

In describing embodiments of the invention, specific terminology is used for the sake of clarity. For the purpose of description, specific terms are intended to at least include technical and functional equivalents that operate in a similar manner to accomplish a similar result. Additionally, in some instances where a particular embodiment of the invention includes a plurality of system elements or method steps, those elements or steps may be replaced with a single element or step; likewise, a single element or step may be replaced with a plurality of elements or steps that serve the same purpose. Further, where parameters for various properties are specified herein for embodiments of the invention, those parameters can be adjusted up or down by 1/100^{th}, 1/50^{th}, 1/20^{th}, 1/10^{th}, ⅕^{th}, ⅓^{rd}, ½, ¾^{th}, etc. (or up by a factor of 2, 5, 10, etc.), or by rounded-off approximations thereof, unless otherwise specified. Moreover, while this invention has been shown and described with references to particular embodiments thereof, those skilled in the art will understand that various substitutions and alterations in form and details may be made therein without departing from the scope of the invention. Further still, other aspects, functions and advantages are also within the scope of the invention; and all embodiments of the invention need not necessarily achieve all of the advantages or possess all of the characteristics described above. Additionally, steps, elements and features discussed herein in connection with one embodiment can likewise be used in conjunction with other embodiments. The contents of references, including reference texts, journal articles, patents, patent applications, etc., cited throughout the text are hereby incorporated by reference in their entirety; and appropriate components, steps, and characterizations from these references optionally may or may not be included in embodiments of this invention. Still further, the components and steps identified in the Background section are integral to this disclosure and can be used in conjunction with or substituted for components and steps described elsewhere in the disclosure within the scope of the invention. In method claims, where stages are recited in a particular order—with or without sequenced prefacing characters added for ease of reference—the stages are not to be interpreted as being temporally limited to the order in which they are recited unless otherwise specified or implied by the terms and phrasing.

What is claimed is:

1. A method for patterning graphene, comprising:
forming a pattern of passivation material on a growth substrate, wherein the pattern of passivation material defines an inverse pattern of exposed surface on the growth substrate; and
supplying a carbon-containing gas to the inverse pattern of the exposed surface of the growth substrate and forming patterned graphene from the carbon, wherein the passivation material does not facilitate graphene growth, and wherein the inverse pattern of exposed surface of the growth substrate facilitates graphene growth on the exposed surface of the growth substrate.

2. The method of claim 1, wherein the exposed surface of the growth substrate includes a catalyst that decomposes the carbon-containing gas to free the carbon for forming the graphene.

3. The method of claim 1, wherein the passivation material includes an exposed ceramic surface.

4. The method of claim 3, wherein the passivation material is formed by depositing a metal layer and oxidizing an exposed surface of the metal layer to form the ceramic surface.

5. The method of claim 3, wherein the ceramic surface includes at least one composition selected from alumina, silica, and silicon nitride.

6. The method of claim 1, wherein the carbon-containing gas includes methane.

7. The method of claim 1, wherein the formation of the passivation material pattern includes a process selected from shadow-mask deposition, lithography and ink-jet printing.

8. The method of claim 1, further comprising removing the pattern of passivation material from the growth substrate after the graphene pattern is formed.

9. The method of claim 1, wherein the growth substrate includes a copper surface on which the pattern of passivation material is formed, and wherein the passivation material is non-alloying with copper.

10. The method of claim 1, wherein the graphene pattern is deposited with at least one pathway having a width no greater than 1 nm.

11. The method of claim 1, further comprising releasing the graphene pattern from the growth substrate.

12. The method of claim 11, further comprising depositing the released graphene pattern on a new substrate.

13. A growth substrate with patterned graphene, comprising:
a growth substrate;
a passivation pattern comprising a material that does not facilitate graphene growth on the growth substrate, wherein the passivation pattern defines an inverse pattern of exposed surface on the growth substrate; and
a graphene pattern formed preferentially on the inverse pattern of growth substrate in comparison with the passivation pattern.

14. The growth substrate of claim 13, wherein the exposed surface of the growth substrate includes a catalyst for decomposing a carbon-containing gas to free the carbon for forming the graphene on the exposed surface.

15. The growth substrate of claim 13, wherein the passivation pattern includes an exposed ceramic surface.

16. The growth substrate of claim 13, wherein the exposed surface of the growth substrate comprises a transition metal.
